(19) United States
(12) Patent Application Publication
(10) Pub. No.: US 2025/0096756 A1
(43) Pub. Date: Mar. 20, 2025

(54) ERROR AMPLIFIER SWITCHING CONVERTER AND A CONTROL METHOD OF ERROR AMPLIFIER

(71) Applicant: Joulwatt Technology Co., Ltd., Hangzhou (CN)

(72) Inventor: Yang CHENG, Hangzhou (CN)

(21) Appl. No.: 18/829,064

(22) Filed: Sep. 9, 2024

(30) Foreign Application Priority Data
Sep. 15, 2023 (CN) 202311196156.7

(51) Int. Cl. H03F 3/45

(52) U.S. Cl. CPC H03F 3/45179; H03F 2200/129

(57) ABSTRACT

The present disclosure provides an error amplifier, a switching converter, and a control method of the error amplifier. The error amplifier includes: an operation module for outputting a regulation signal according to a difference between a feedback voltage and a reference voltage, wherein the feedback voltage represents an output voltage of the switching converter, and the regulation signal is used to regulate an output current of the switching converter; a regulation module for regulating a transconductance of the operation module according to an absolute value of the difference between the feedback voltage and the reference voltage or an absolute value of the regulation signal. When an output of the switching converter changes greatly, the transconductance of the error amplifier is increased in real time, thereby a bandwidth is increased to achieve a fast response of the switching converter. The switching converter has high stability when the output is normal.

### CROSS-REFERENCE TO RELATED APPLICATIONS

This present disclosure claims priority to a Chinese patent application No. 202311196156.7, filed on Sep. 15, 2023, and entitled “error amplifier switching converter and a control method of error amplifier”, the entire contents of which are incorporated herein by reference, including the specification, claims, drawings and abstract.

### FIELD OF TECHNOLOGY

The present disclosure relates to a field of operational transconductance amplifier (OTA), and in particular, to an error amplifier, a switching converter, and a control method of the error amplifier.

### BACKGROUND

An input signal of an operational transconductance amplifier is voltage, an output signal is current, and the gain is transconductance. Trans-conductance amplifiers are mainly applied in two aspects: (1) performing signal operations and processing in a variety of linear and nonlinear analog circuits and systems; (2) serving as an interface circuit between a voltage mode signal system and a current mode signal system, converting a voltage signal to a current signal which is sent to the current mode signal system for processing.

The operational transconductance amplifier is required to have low static power consumption and high transient response when being applied in low dropout regulator (LDO) and direct current-direct current (DC-DC) as an error amplifier. When the operational transconductance amplifier is applied to the DC-DC system, if the load jumps rapidly and dynamically, there will be a large overshoot or drop in an output of the operational transconductance amplifier. In the prior art, a fast response is achieved by increasing a bandwidth of the DC-DC system to reduce the overshoot or drop. However, the way of increasing the bandwidth could cause instability in the DC-DC system.

Therefore, there is an urgent need in the existing technology for a solution that can solve the DC-DC system output with large overshoot or drop without affecting the stability of the DC-DC system.

### SUMMARY

In order to solve the technical problems in the prior art that affect the stability of the DC-DC system by increasing the bandwidth to solve the large overshoot or drop of the output of DC-DC system, the present disclosure provides an error amplifier, a switching converter and a control method of error amplifier. The error amplifier includes:
an operation module, configured to output a regulation signal according to a difference between a feedback voltage and a reference voltage, wherein the feedback voltage represents an output voltage of the switching converter, and the regulation signal is used to regulate an output current of the switching converter;
a regulation module, configured to regulate a transconductance of the operation module according to an absolute value of the difference between the feedback voltage and the reference voltage upon the absolute value of the difference between the feedback voltage and the reference voltage is greater than or equal to a preset difference threshold; or regulate the transconductance of the operation module according to an absolute value of the regulation signal upon the absolute value of the regulation signal is greater than or equal to a preset threshold.

Further, upon the absolute value of the difference between the feedback voltage and the reference voltage is less than the preset difference threshold, or the absolute value of the regulation signal is less than the preset threshold, the transconductance of the operation module remains unchanged.

Further, the regulation module controls the transconductance to be positively correlated with the absolute value of the difference between the feedback voltage and the reference voltage, or controls the transconductance to be positively correlated with the absolute value of the regulation signal.

Optionally, the operation module includes a differential input unit, a current mirror unit and a tail current unit,
the tail current unit provides a preset tail current to the differential input unit, the differential input unit converts the feedback voltage to a first current, the reference voltage to a second current, and the current mirror unit outputs the regulation signal according to a difference between the first current and the second current.

Optionally, the regulation module includes a tail current regulation unit that regulates a total tail current of the operation module according to the absolute value of the difference between the feedback voltage and the reference voltage, or regulates the total tail current of the operation module according to the absolute value of the regulation signal.

Optionally, the tail current regulation unit includes a first pair of differential input transistors and a first current mirror assembly, an output terminal of the first current mirror assembly is connected to the differential input unit, the first pair of differential input transistors convert the feedback voltage to a first regulation current, convert the reference voltage to a second regulation current, and the first current mirror assembly outputs a third regulation current according to the absolute value of a difference between the first regulation current and the second regulation current.

Optionally, the tail current regulation unit includes a third current mirror assembly, a reference terminal of the third current mirror assembly is connected to an output terminal of the current mirror unit, an output terminal of the third current mirror assembly is connected to the differential input unit, and outputs a seventh regulation current according to an absolute value of the regulation signal.

Optionally, the regulation module includes a proportional factor regulation unit, the proportional factor regulation unit regulates a proportional factor of the current mirror unit according to the absolute value of the difference between the feedback voltage and the reference voltage, or regulates the proportional factor of the current mirror unit according to the absolute value of the regulation signal, wherein
the proportional factor represents a ratio of an output current of the current mirror unit to a reference current.

Optionally, the proportional factor regulation unit includes a second pair of differential input transistors, a second current mirror assembly and a resistor assembly, the resistor assembly is connected between an output terminal of the second current mirror assembly and a reference terminal of the current mirror unit, the second pair of differential input transistors convert the feedback voltage to a fourth regulation current and the reference voltage to a fifth regulation current, the second current mirror assembly outputs a sixth regulation current according to an absolute value of a difference between the fourth regulation current and the fifth regulation current, and the sixth regulation current flowing through the resistor assembly.

A switching converter includes the above-mentioned error amplifier.

A control method for an error amplifier. The error amplifier is used for a switching converter. The control method includes:
regulating a transconductance of the error amplifier according to an absolute value of a difference between a feedback voltage and a reference voltage, or regulating the transconductance of the error amplifier according to an absolute value of a regulation signal, wherein

The feedback voltage represents an output voltage of the switching converter, the regulation signal is acquired according to a difference between the feedback voltage and the reference voltage, and is used to regulate an output current of the switching converter.

Further, regulating a transconductance of the error amplifier according to an absolute value of a difference between a feedback voltage and a reference voltage, or regulating the transconductance of the error amplifier according to an absolute value of a regulation signal includes:
in a first regulation state, controlling the transconductance of the operation module unchanged;
in a second regulation state, controlling the transconductance of the operation module to be positively correlated with the absolute value of the difference between the feedback voltage and the reference voltage, or controlling the transconductance of the operation module to be positively correlated with the absolute value of the regulation signal, wherein
the absolute value of the difference between the feedback voltage and the reference voltage in the first regulation state is less than a preset difference threshold, or the absolute value of the regulation signal is less than a preset threshold;
in the second regulation state, the absolute value of the difference between the feedback voltage and the reference voltage is greater than or equal to the preset difference threshold, or the absolute value of the regulation signal is greater than or equal to the preset threshold.

In summary, when the output of the switching converter changes greatly, the error amplifier of the present disclosure increases the transconductance of the error amplifier according to the absolute value of the difference between the feedback voltage and the reference voltage or the absolute value of the regulation signal in real time, thereby increasing the bandwidth of the switching converter to achieve a fast response of the switching converter. At the same time, when the output of the switching converter is normal, the transconductance of the control error amplifier is controlled to remain unchanged, thereby ensuring that the switching converter has high stability when the output is normal.

### BRIEF DESCRIPTION OF THE DRAWINGS

FIG. 1 is an error amplifier with a transconductance regulated by a feedback voltage and a reference voltage according to the present disclosure;

FIG. 2 is an error amplifier with transconductance regulated by a regulation signal according to the present disclosure;

FIG. 3 shows an overall structure of an error amplifier of a first embodiment;

FIG. 4 shows a specific circuit structure of the error amplifier of the first embodiment;

FIG. 5 shows an overall structure of an error amplifiers of a second embodiment;

FIG. 6 shows a specific circuit structure of the error amplifier of the second embodiment;

FIG. 7 shows an overall structure of an error amplifier of a third embodiment;

FIG. 8 shows a specific circuit structure of the error amplifier of the third embodiment.

### DETAILED DESCRIPTION

Some preferred embodiments of the present disclosure will be described in detail below in conjunction with drawings, but the present disclosure is not limited thereto.

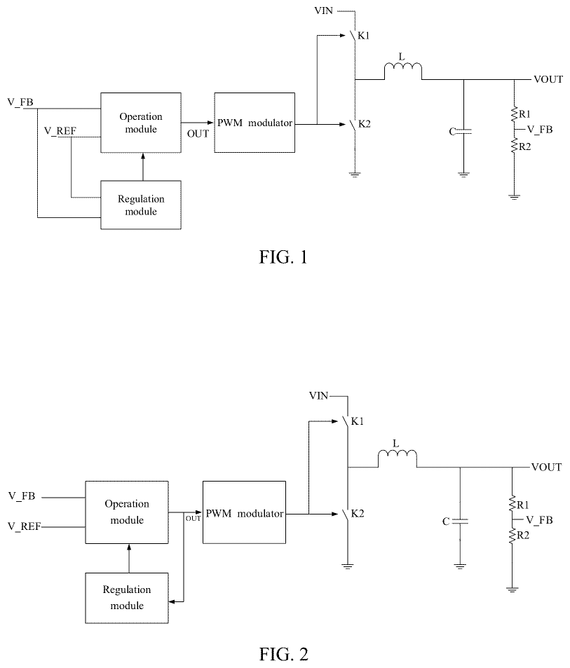

Technology solutions of the prior art achieving a fast response of a DC-DC system by increasing a bandwidth of the DC-DC system to reduce a large overshoot or drop in the output of the DC-DC system could lead to poor stability of the DC-DC system. The present disclosure provides an error amplifier applied in a switching converter, as shown in FIGS. 1 and 2, the error amplifier includes:
an operation module, the operation module converts a difference between a feedback voltage and a reference voltage and outputs a regulation signal. The feedback voltage represents an output voltage of the switching converter, and the regulation signal is used to regulate an output current of the switching converter. According to the principle and structure of the error amplifier, the regulation signal is a current signal;
a regulation module, the regulation module regulates a transconductance of the operation module according to an absolute value of the difference between the feedback voltage and the reference voltage when the absolute value of the difference between the feedback voltage and the reference voltage is greater than or equal to a preset difference threshold, or regulates the transconductance of the operation module according to an absolute value of the regulation signal when the absolute value of the regulation signal is greater than or equal to a preset threshold;
wherein, when the absolute value of the difference between the feedback voltage and the reference voltage is equal to the preset difference threshold, the absolute value of the regulation signal is the preset threshold.

Further, when the absolute value of the difference between the feedback voltage and the reference voltage is less than the preset difference threshold or the absolute value of the regulation signal is less than the preset threshold, the transconductance of the operation module is unchanged.

Further, the regulation module controls the transconductance to be positively correlated with the absolute value of the difference between the feedback voltage and the reference voltage, or controls the transconductance to be positively correlated with the absolute value of the regulation signal.

Wherein, a positive correlation factor representing the positive correlation is set according to an overshoot amplitude or drop amplitude of the output voltage of the switching converter. The preset difference threshold and the preset threshold are set according to specific structure and use requirements of the switching converter. The preset difference threshold and the preset threshold are values greater than or equal to zero. If the preset difference threshold is not equal to zero, the preset difference threshold should be greater than a ripple voltage of the switching converter, so as to avoid frequent changes in the transconductance of the operation module.

It could be seen that when the output of the switching converter changes greatly, that is, when the absolute value of the difference between the feedback voltage and the reference voltage is greater than or equal to the preset difference threshold or the absolute value of the regulation signal output by the error amplifier is greater than or equal to the preset threshold, the transconductance of the error amplifier of the present disclosure is regulated in real time according to the absolute value of the difference between the feedback voltage and the reference voltage or the absolute value of the regulation signal, thereby increasing the bandwidth of the switching converter to achieve a fast response of the switching converter. At the same time, when the output of the switching converter is normal, that is, when the absolute value of the difference between the feedback voltage and the reference voltage is less than the preset difference threshold or the absolute value of the regulation signal output by the error amplifier is less than the preset threshold, the transconductance of the error amplifier is controlled to remain unchanged, thereby ensuring that the switching converter has high stability when the output is normal.

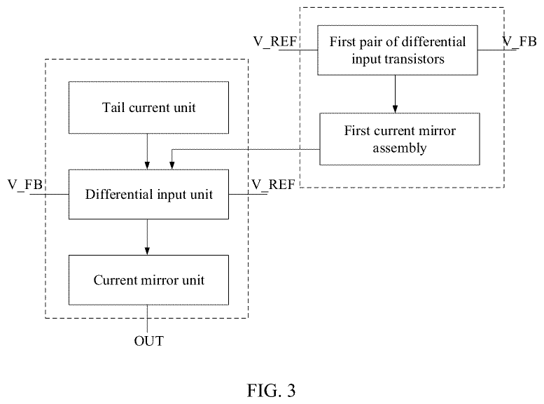

Optionally, in a first embodiment, as shown in FIG. 3, the operation module includes: a differential input unit, a current mirror unit and a tail current unit. The tail current unit provides a preset tail current to the differential input unit. The preset tail current determines the transconductance of the operation module (an initial transconductance of the operation module that is not regulated). The differential input unit converts the feedback voltage to a first current and the reference voltage to a second current. The current mirror unit outputs a regulation signal according to a difference between the first current and the second current. The regulation module includes a tail current regulation unit, and the tail current regulation unit includes a first pair of differential input transistors and a first current mirror assembly. The first pair of differential input transistors converts the feedback voltage to a first regulation current and a reference voltage to a second regulation current. The first current mirror assembly outputs a third regulation current according to the absolute value of a difference between the first regulation current and the second regulation current. An output terminal of the first current mirror assembly is connected to the differential input unit, and the third regulation current output by the first current mirror assembly flows into the differential input unit.

Wherein, the tail current regulation unit outputs the third regulation current according to the absolute value of the difference between the feedback voltage and the reference voltage, so that a total tail current of the operation module is increased, thereby increasing the transconductance of the operation module. Further, as the absolute value of the difference between the feedback voltage and the reference voltage increases (decreases), the third regulation current increases (decreases), a sum of the third regulation current and a preset tail current increase (decreases), and the transconductance of the operation module also increases (decreases). That is, the transconductance of the operation module is positively correlated with the absolute value of the difference between the feedback voltage and the reference voltage. It should be noted that if the transconductance is regulated for the first time, the regulated transconductance is increased compared to the initial transconductance that is not regulated. However, in the whole process, it is possible to regulate the transconductance several times. In the process of transconductance change, since the transconductance is positively correlated with the absolute value of the difference between the feedback voltage and the reference voltage, if the absolute value of the difference between the feedback voltage and the reference voltage gradually increases over a period of time, the transconductance will gradually increase; If the absolute value of the difference between the feedback voltage and the reference voltage increases first and then decreases over a period of time, the transconductance increases first and then decreases. The transconductance could be increased or decreased within a changing range, but the changed transconductance is greater than the initial transconductance that is not regulated. Similarly, the above transconductance change process is also applicable to regulating the transconductance according to the absolute value of the regulation signal.

Wherein, when the first pair of differential input transistors of the tail current regulation unit operates in a saturation region, the transconductance of the operation module regulated by the tail current regulation unit is satisfied:

gm′ is proportional to \sqrt{|V_FB−V_REF|*K+I}, where V_FB represents the feedback voltage, V_REF represents the reference voltage, gm′ represents the transconductance after the error amplifier is regulated, K represents a proportional factor of the first current mirror assembly (the proportional factor of the first current mirror assembly represents a ratio of an output current of the first current mirror assembly to a reference current of the first current mirror assembly), and I is the third regulation current output by the first current mirror assembly.

Therefore, in a case that load changes, if the output of the switching converter changes greatly, the regulation module will dynamically regulate the transconductance of the operation module according to the absolute value of the difference between the feedback voltage and the reference voltage, and dynamically regulate the bandwidth of the switching converter, so as to achieve a fast response of the switching converter.

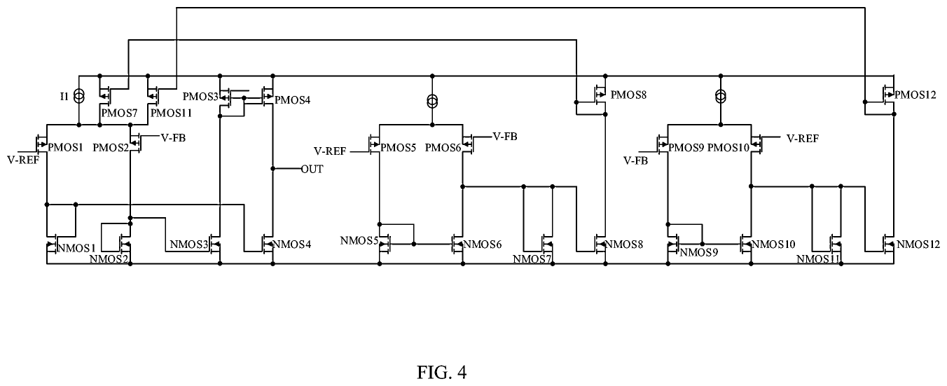

Specifically, as shown in FIG. 4, the operation module includes: PMOS1, PMOS2, PMOS3, PMOS4, NMOS1, NMOS2, NMOS3, NMOS4 and current source I1, wherein PMOS1 and PMOS2 form the differential input unit, NMOS1, NMOS2, NMOS3, NMOS4, PMOS3 and PMOS4 form the current mirror unit, and current source I1 is the tail current unit. The sources of PMOS1 and PMOS2 are coupled and connected to the current source I1. The gate of PMOS1 receives reference voltage V-REF. The gate of PMOS2 receives feedback voltage V-FB. The drain of PMOS1 is connected to the drain of NMOS1. The drain of PMOS2 is connected to the drain of NMOS2. The gate of NMOS1 is connected to the drain of NMOS1. The gate of NMOS2 is connected to the drain of NMOS2. The gate of NMOS3 is connected to the drain of NMOS2. The drain of NMOS3 is connected to the drain of PMOS3. The gate of NMOS4 is connected to the gate of NMOS1. The source of NMOS4 is connected to the source of NMOS1. The drain of NMOS4 is connected to the drain of PMOS4. The gate of PMOS4 is connected to the gate of PMOS3. The gate of PMOS3 is connected to the drain of PMOS3. The source of PMOS3 is connected to the source of PMOS4. The output terminal of the operation module is set between PMOS4 and NMOS4.

Further, the tail current regulation unit includes: PMOS5, PMOS6, PMOS7, PMOS8, NMOS5, NMOS6, NMOS7, NMOS8, PMOS9, PMOS10, PMOS11, PMOS12, NMOS9, NMOS10, NMOS11, and NMOS12, wherein the first pair of differential input transistors includes PMOS5, PMOS6, PMOS9 and PMOS10, and the first current mirror assembly includes PMOS7, PMOS8, NMOS5, NMOS6, NMOS7, NMOS8, PMOS11, PMOS8, NMOS9, NMOS10, NMOS11 and NMOS12. Specifically, the sources of PMOS5 and PMOS6 are coupled and connected to a current source, the gate of PMOS5 receives a reference voltage V-REF, the gate of PMOS6 receives a feedback voltage V-FB, the drain of PMOS5 is connected to the drain of NMOS5, the drain of PMOS6 is connected to the drain of NMOS6, the gate of NMOS5 is connected to the gate of NMOS6, the gate of NMOS5 is connected to the drain of NMOS5, the source of NMOS5 is connected to the source of NMOS6, the gate of NMOS7 is connected to the drain of NMOS7, the drain of NMOS7 is connected to the drain of PMOS6, the gate of NMOS8 is connected to the drain of NMOS7, the source of NMOS7 is connected to the source of NMOS8, the drain of NMOS8 is connected to the drain of PMOS8, the source of PMOS8 is connected to the source of PMOS7, the gate of PMOS7 is connected to the gate of PMOS8, the drain of PMOS7 is connected to the source of PMOS1, and the gate of PMOS8 is connected to the drain of PMOS8. The sources of PMOS9 and PMOS10 are coupled and connected to a current source, the gate of PMOS9 receives a feedback voltage V-FB, the gate of PMOS10 receives a reference voltage V-REF, the drain of PMOS9 is connected to a drain of NMOS9, the drain of PMOS10 is connected to a drain of NMOS10, the gate of NMOS9 is connected to a drain of NMOS9, the source of NMOS9 is connected to a drain of NMOS10, the gate of NMOS11 is connected to a drain of NMOS11, the drain of NMOS11 is connected to a drain of PMOS11, the source of NMOS11 is connected to a drain of NMOS12, the drain of NMOS12 is connected to a drain of PMOS12, the source of PMOS12 is connected to a drain of PMOS11, the gate of PMOS11 is connected to a drain of PMOS11, the source of PMOS11 is connected to a drain of PMOS1, and the drain of PMOS12 is connected to a drain of PMOS12.

In addition, the regulation module further includes a judgment unit that controls whether PMOS5 and PMOS6, PMOS9 and PMOS10 receive the feedback voltage and the reference voltage according to the absolute value of the difference between the feedback voltage and the reference voltage. Specifically, when the reference voltage is greater than the feedback voltage and the difference between the reference voltage and the feedback voltage is greater than or equal to the preset difference threshold, the judgment unit controls the reference voltage and the feedback voltage to be transmitted to PMOS5 and PMOS6, thereby generating the third regulation current; when the difference between the reference voltage and the feedback voltage is less than the preset difference threshold, the judgment unit prevents the reference voltage and the feedback voltage from being transmitted to PMOS5 and PMOS6. When the feedback voltage is greater than the reference voltage and the difference between the feedback voltage and the reference voltage is greater than or equal to the preset difference threshold, the judgment unit controls the reference voltage and the feedback voltage to be transmitted to PMOS9 and PMOS10, thereby generating the third regulation current; When the difference between the feedback voltage and the reference voltage is less than the preset difference threshold, the judgment unit prevents the reference voltage and the feedback voltage from being transmitted to PMOS9 and PMOS10. Therefore, when the third regulation current output by the regulation module is 0, the total tail current of the operation module is the preset tail current, and the transconductance of the operation module remains unchanged; when the third regulation current output by the regulation module is not 0, the total tail current of the operation module is the sum of the preset tail current and the third regulation current, and the transconductance of the operation module is increased.

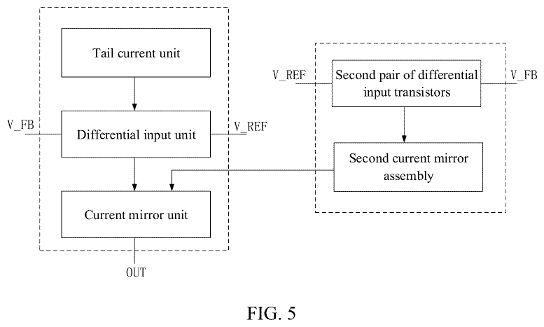

Optionally, in a second embodiment, as shown in FIG. 5, the operation module includes a differential input unit, a current mirror unit, and a tail current unit. The tail current unit provides a preset tail current to the differential input unit. The differential input unit converts the feedback voltage into a first current and the reference voltage into a second current. The current mirror unit outputs a regulation signal according to the difference between the first current and the second current. The regulation module includes a proportional factor regulation unit, the proportional factor regulation unit is configured to increase the proportional factor of the current mirror unit according to the absolute value of the difference between the feedback voltage and the reference voltage, or to increase the proportional factor of the current mirror unit according to the absolute value of the regulation signa. The proportional factor of the current mirror unit represents the ratio of the output current of the current mirror unit to the reference current of the current mirror unit. Specifically, the proportional factor regulation unit includes a second pair of differential input transistors, a second current mirror assembly, and a resistor assembly. The second pair of differential input transistors convert the feedback voltage to a fourth regulation current, convert the reference voltage to a fifth regulation current. The second current mirror assembly outputs a sixth regulation current according to an absolute value of a difference between the fourth regulation current and the fifth regulation current. The resistor assembly is connected between an output terminal of the second current mirror assembly and a reference terminal of the current mirror unit, and the reference terminal of the current mirror unit receives the reference current output from the differential input unit. The sixth regulation current output by the second current mirror assembly flows through the resistor assembly to generate a voltage difference on the resistor assembly, so that a voltage drop is also generated on the reference terminal of the current mirror unit, thereby changing the proportional factor of the current mirror unit. Wherein, the proportional factor regulation unit outputs the sixth regulation current according to the absolute value of the difference between the feedback voltage and the reference voltage, so that the reference terminal of the current mirror unit generates a certain voltage drop, thereby increasing the proportional factor of the current mirror unit, and finally increasing the transconductance of the operation module. Further, as the absolute value of the difference between the feedback voltage and the reference voltage increases (decreases), the sixth regulation current increases (decreases), the voltage drop at the reference end of the current mirror unit increases (decreases), the proportional factor of the current mirror unit increases (decreases), and the transconductance of the operation module also increases (decreases). That is, the transconductance of the operation module is positively correlated with the absolute value of the difference between the feedback voltage and the reference voltage.

Wherein, the transconductance regulated by the proportional factor regulation unit of the operation module satisfies:

gm′=gm*(Veff+IR)²/Veff², where gm′ represents the regulated transconductance of the operation module, gm represents an original transconductance of the operation module, Veff represents an over-driving voltage of transistors in the current mirror unit, I represents a current flowing through the resistor assembly (that is, the sixth regulation current), and R represents a resistance value of the resistor assembly.

Therefore, in a case that load changes, if the output of the switching converter changes greatly, the regulation module will dynamically adjust the transconductance of the operation module according to the absolute value of the difference between the feedback voltage and the reference voltage, thereby dynamically adjusting the bandwidth of the switching converter, so as to achieve a fast response of the switching converter.

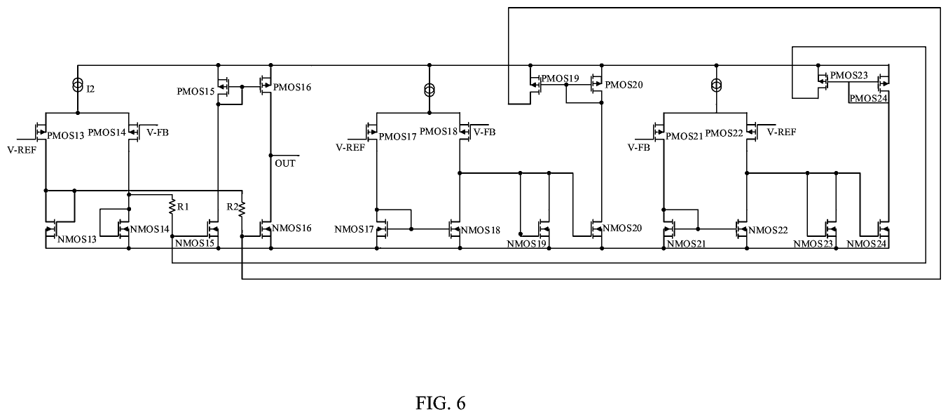

Specifically, as shown in FIG. 6, the operation module includes: PMOS13, PMOS14, PMOS15, PMOS16, NMOS13, NMOS14, NMOS15, NMOS16, resistor R1, resistor R2 and current source 12, wherein PMOS13 and PMOS14 form the differential input unit, NMOS13, NMOS14, NMOS15, NMOS16, PMOS15 and PMOS16 form the current mirror unit, and current source 12 is the tail current unit. The sources of PMOS13 and PMOS14 are coupled and connected to the current source 12, the gate of PMOS13 receives a reference voltage V-REF, the gate of PMOS14 receives a feedback voltage V-FB, the drain of PMOS13 is connected to the drain of NMOS13, the drain of PMOS14 is connected to the drain of NMOS14, the gate of NMOS13 is connected to the drain of NMOS13, the gate of NMOS16 is connected to the resistors R2 and the gate of NMOS13 in turn, the source of NMOS13 is connected to the source of NMOS16, The gate of NMOS14 is connected to the drain of NMOS14, the gate of NMOS15 is connected to the resistors R1 and the gate of NMOS14 in turn, the source of NMOS14 is connected to the source of NMOS15, the drain of NMOS15 is connected to the drain of PMOS15, the drain of NMOS16 is connected to the drain of PMOS16, the gate of PMOS15 is connected to the gate of PMOS16, the gate of PMOS15 is connected to the drain of PMOS15, the source of PMOS15 is connected to the source of PMOS16, and the output terminal of the operation module is set between PMOS16 and NMOS16.

Further, the proportional factor regulation unit includes: PMOS17, PMOS18, PMOS19, PMOS20, NMOS17, NMOS18, NMOS19, NMOS20, PMOS21, PMOS22, PMOS23, PMOS24, NMOS21, NMOS22, NMOS23 and NMOS24. Wherein, the second pair of differential input transistors includes PMOS17, PMOS18, PMOS21 and PMOS22, the second current mirror assembly includes PMOS19, PMOS20, NMOS17, NMOS18, NMOS19, NMOS20, PMOS23, PMOS24, NMOS21, NMOS22, NMOS23 and NMOS24, and the resistor assembly includes resistor R1 and resistor R2. The sources of PMOS17 and PMOS18 are coupled and connected to a current source, the gate of PMOS17 receives the reference voltage V-REF, the gate of PMOS18 receives the feedback voltage V-FB, the drain of PMOS17 is connected to the drain of NMOS17, the drain of PMOS18 is connected to the drain of NMOS18, the gate of NMOS17 is connected to the gate of NMOS18, the gate of NMOS17 is connected to the drain of NMOS17, the source of NMOS17 is connected to the source of NMOS18, the gate of NMOS19 is connected to the drain of NMOS19, the drain of NMOS19 is connected to the drain of PMOS18, the gate of NMOS20 is connected to the drain of NMOS19, the source of NMOS19 is connected to the source of NMOS20, the drain of NMOS20 is connected to the drain of PMOS20, the source of PMOS19 is connected to the source of PMOS20, the gate of PMOS19 is connected to the gate of PMOS20, the drain of PMOS20 is connected to the gate of PMOS20, the drain of PMOS19 is connected to one end of resistor R2 and the gate of NMOS16, and the other end of resistor R2 is connected to the drain of NMOS13. The sources of PMOS21 and PMOS22 are coupled and connected to a current source, the gate of PMOS21 receives the feedback voltage V-FB, the gate of PMOS22 receives the reference voltage V-REF, the drain of PMOS21 is connected to the drain of NMOS21, the drain of PMOS22 is connected to the drain of NMOS22, the gate of NMOS21 is connected to the gate of NMOS21, the gate of NMOS21 is connected to the drain of NMOS21, the source of NMOS21 is connected to the source of NMOS22, the gate of NMOS23 is connected to the drain of NMOS23, the drain of NMOS23 is connected to the drain of PMOS22, the gate of NMOS24 is connected to the drain of NMOS23, the source of NMOS23 is connected to the source of NMOS24, the drain of NMOS24 is connected to the drain of PMOS24, the source of PMOS23 is connected to the source of PMOS24, the gate of PMOS23 is connected to the gate of PMOS24, the gate of PMOS24 is connected to the drain of PMOS24, the drain of PMOS23 is connected to one end of resistor R1 and the gate of NMOS15, and the other end of resistor R1 is connected to the drain of NMOS14.

In addition, the regulation module further includes a judgment unit that controls whether PMOS17 and PMOS18, PMOS21 and PMOS22 receive the feedback voltage and the reference voltage according to the absolute value of the difference between the feedback voltage and the reference voltage. Specifically, when the reference voltage is greater than the feedback voltage and the difference between the reference voltage and the feedback voltage is greater than or equal to the preset difference threshold, the judgment unit controls the reference voltage and the feedback voltage to be transmitted to PMOS17 and PMOS18, thereby generating the sixth regulation current; when the difference between the reference voltage and the feedback voltage is less than the preset difference threshold, the judgment unit prevents the reference voltage and the feedback voltage from being transmitted to PMOS17 and PMOS18. When the feedback voltage is greater than the reference voltage and the difference between the feedback voltage and the reference voltage is greater than or equal to the preset difference threshold, the judgment unit controls the reference voltage and the feedback voltage to be transmitted to PMOS21 and PMOS22, thereby generating the sixth regulation current; When the difference between the feedback voltage and the reference voltage is less than the preset difference threshold, the judgment unit prevents the reference voltage and the feedback voltage from being transmitted to PMOS21 and PMOS22. Therefore, when the sixth regulation current output by the regulation module is 0, the proportional factor of the current mirror unit remains unchanged, and the transconductance of the operation module remains unchanged; When the sixth regulation current output by the regulation module is not 0, the output terminal of the current mirror unit generates a voltage drop, the proportional factor of the current mirror unit becomes larger, and the transconductance of the operation module increases.

The above embodiments are all about regulating the transconductance of the error amplifier according to the absolute value of the difference between the feedback voltage and the reference voltage. The following describes in the third embodiment how to adjust the transconductance of the error amplifier according to the absolute value of the regulation signal. However, it should be noted that, there is an equivalent mathematical relationship between the regulation signal output by the error amplifier and the difference between the reference voltage and the feedback voltage, so the regulation of the transconductance according to the absolute value of the regulation signal and the regulation of the transconductance according to the absolute value of the difference between the feedback voltage and the reference voltage are essentially the same, but the difference between the two is an equivalent conversion.

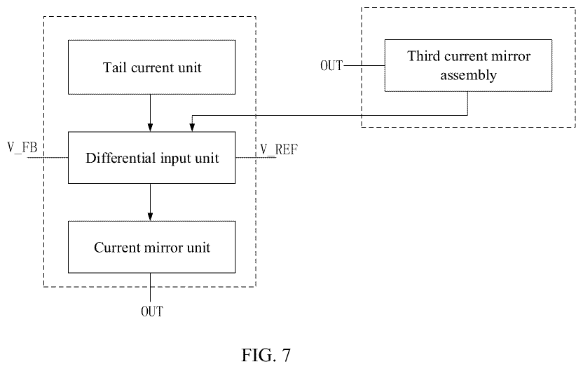

Optionally, in the third embodiment, as shown in FIG. 7, the operation module includes: a differential input unit, a current mirror unit and a tail current unit. The tail current unit provides a preset tail current to the differential input unit, and the preset tail current decide the transconductance of the operation module. The differential input unit converts a feedback voltage to a first current, the reference voltage to a second current, and the current mirror unit outputs a regulation signal according to a difference between the first current and the second current.

The regulation module includes a tail current regulation unit, and the tail current regulation unit includes a third current mirror assembly. A reference terminal of the third current mirror assembly is connected to an output terminal of the current mirror unit, and an output terminal of the third current mirror assembly is connected to the differential input unit. The third current mirror assembly outputs a seventh regulation current according to an absolute value of the regulation signal, and the seventh regulation current flows into the differential input unit.

That is, the tail current regulation unit outputs the seventh regulation signal according to the absolute value of the regulation signal, so that a total tail current of the operation module is increased, thereby increasing the transconductance of the operation module. Further, as the absolute value of the regulation signal increases (decreases), the seventh regulation current increases (decreases), and a sum of the seventh adjustment current and the preset tail current increases (decreases), the transconductance of the operation module also increases (decreases). That is, the transconductance of the operation module is positively correlated with the absolute value of the regulation signal.

Wherein, by setting the proportional factor of the third current mirror assembly, the output current of the third current mirror assembly could be controlled to be proportional to the absolute value of the regulation signal, then the total tail current of the operation module is a sum of the preset tail current and the seventh regulation current. As the absolute value of the regulation signal increases (decreases), the seventh regulation current increases (decreases), the total tail current of the operation module increases (decreases), and the transconductance of the operation module increases (decreases) Wherein, the proportional factor of the third current mirror assembly is a ratio of the output current of the third current mirror assembly to the reference current of the third current mirror assembly.

Therefore, in a case that load changes, if the output of the switching converter changes greatly, the regulation module will dynamically adjust the transconductance of the operation module according to the absolute value of the regulation signal, thereby dynamically adjusting the bandwidth of the switching converter, so as to achieve a fast response of the switching converter.

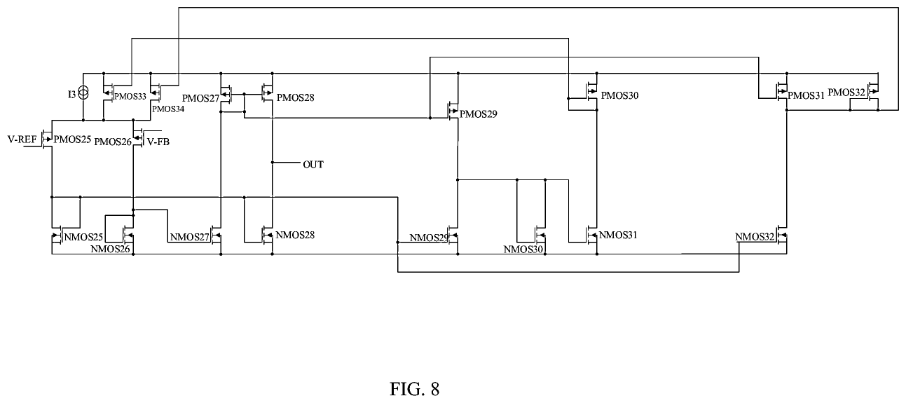

Specifically, as shown in FIG. 8, the operation module includes: PMOS25, PMOS26, PMOS27, PMOS28, NMOS25, NMOS26, NMOS27, NMOS28 and current source 13, wherein PMOS25 and PMOS 26 forms the differential input unit, NMOS25, NMOS26, NMOS27, NMOS28, PMOS27 and PMOS28 forms the current mirror unit, and current source 13 is the tail current unit. The sources of PMOS25 and PMOS26 are coupled and connected to the current source 13, the gate of PMOS25 receives a reference voltage V-REF, the gate of PMOS26 receives a feedback voltage V-FB, the drain of PMOS25 is connected to the drain of NMOS25, the drain of PMOS26 is connected to the drain of NMOS26, the gate of NMOS25 is connected to the drain of NMOS25, and the gate of NMOS26 is connected to the drain of NMOS26, the gate of NMOS27 is connected to the drain of NMOS26, the source of NMOS27 is connected to the source of NMOS26, the drain of NMOS27 is connected to the drain of PMOS27, the gate of NMOS28 is connected to the gate of NMOS25, the source of NMOS28 is connected to the source of NMOS25, the drain of NMOS28 is connected to the drain of PMOS28, the gate of PMOS28 is connected to the gate of PMOS27, the gate of PMOS27 is connected to the drain of PMOS27, the source of PMOS27 is connected to the source of PMOS28, and the output terminal OUT of the operation module is set between PMOS28 and NMOS28.

Further, the third current mirror assembly includes: PMOS29, PMOS30. PMOS31. PMOS32, PMOS33, PMOS34, NMOS29, NMOS30, NMOS31 and NMOS32 Wherein, the gate of NMOS29 is connected to the gate of NMOS25, the source of NMOS29 is connected to the source of NMOS25, the drain of NMOS29 is connected to the drain of PMOS29, the gate of PMOS29 is connected to the gate of PMOS28, the source of PMOS29 is connected to the source of PMOS28, the gate and drain of NMOS30 are connected to the drain of NMOS29, and the source of NMOS30 is connected to the source of NMOS29, the gate of NMOS31 is connected to the gate of NMOS30, the source of NMOS31 is connected to the source of NMOS30, the drain of PMOS30 is connected to the drain of NMOS31, the source of PMOS30 is connected to the source of PMOS29, the gate of PMOS30 is connected to the gate of PMOS33, the gate of PMOS30 is connected to the drain, the drain of PMOS33 is connected to the source of PMOS26, and the source of PMOS33 is connected to the source of PMOS27. The gate of NMOS32 is connected to the gate of NMOS25, the source of NMOS32 is connected to the source of NMOS25, the drain of NMOS32 is connected to the drain of PMOS31 and PMOS32, the gate of PMOS31 is connected to the gate of PMOS28, the source of PMOS31 and PMOS32 is connected to the source of PMOS28, the gate of PMOS32 is connected to the drain, and the drain of PMOS32 is connected to the gate of PMOS34, the drain of PMOS34 is connected to the source of PMOS26, and the source of PMOS34 is connected to the source of PMOS27.

In addition, the regulation module further includes a judgment unit that controls whether the third current mirror assembly receives the regulation signal according to the absolute value of the regulation signal. It could be seen that when the reference voltage V-REF is greater than the feedback voltage V-FB and the absolute value of the regulation signal is greater than or equal to the preset threshold, the regulation signal output by the current mirror unit is transmitted to NMOS30 by use of NMOS29 and PMOS29, the regulation signal with two times of mirror amplification is transmitted to PMOS33 by use of NMOS31 and PMOS30, and is further transmitted to the differential input unit through PMOS33, so that the total tail current of the differential input unit is increased, so as to increase the transconductance of the differential input unit; When the reference voltage V-REF is less than the feedback voltage V-FB and the absolute value of the regulation signal is greater than or equal to the preset threshold, the regulation signal output by the current mirror unit is transmitted to PMOS32 by use of NMOS32 and PMOS31, the regulation signal after mirror amplification is transmitted to PMOS34 by use of PMOS32, and is further transmitted to the differential input unit through PMOS34, so that the total tail current of the differential input unit is increased.

The present disclosure further provides a switching converter including an above-mentioned error amplifier.

The present disclosure further provides a control method for an error amplifier. The error amplifier is used for a switching converter. The error amplifier outputs a regulation signal according to a difference between a feedback voltage and a reference voltage. The feedback voltage represents an output voltage of the switching converter. The regulation signal is used to regulate an output current of the switching converter. The control method includes:

Regulating a transconductance of the error amplifier according to an absolute value of a difference between the feedback voltage and the reference voltage, or regulating the transconductance of the error amplifier according to an absolute value of the regulation signal.

Further, regulating a transconductance of the operation module according to the absolute value of the difference between the feedback voltage and the reference voltage, or regulating the transconductance of the operation module according to the absolute value of the regulation signal includes:
In a first regulation state, controlling the transconductance of the operation module unchanged;
In a second regulation state, controlling the transconductance of the operation module to be positively correlated with the absolute value of the difference between the feedback voltage and the reference voltage, or controlling the transconductance of the operation module to be positively correlated with the absolute value of the regulation signal, wherein
in the first regulation state, the absolute value of the difference between the feedback voltage and the reference voltage is less than a preset difference threshold, or the absolute value of the regulation signal is less than a preset threshold;
In the second regulation state, the absolute value of the difference between the feedback voltage and the reference voltage is greater than or equal to the preset difference threshold, or the absolute value of the regulation signal is greater than or equal to the preset threshold.

In addition, when the absolute value of the difference between the feedback voltage and the reference voltage is equal to the preset difference threshold, the absolute value of the regulation signal output by the error amplifier is the preset threshold.

As shown in FIGS. 1 to 8, it should be understood that the various modules, units, described in the present disclosure, all has an actual circuit structure and can may also be referred to as circuits, or integrated into a structure such as a chip, processor, or the like. For example, the operation module may also be referred to as an operation circuit, the regulation module may also be referred to as a regulation circuit, the differential input unit may also be referred to as a differential input circuit, the current mirror unit may also be referred to as a current mirror circuit, and a tail current unit may also be referred to as a tail current circuit.

Preferred embodiments according to the present disclosure have been described in detail above, but the circuits and beneficial effects of the patent should not be considered to be limited only to those described above. The disclosed embodiments and drawings can better understand the present disclosure. Therefore, the contents of the disclosed embodiments and drawings are for better understanding of the present disclosure. The protection of the present disclosure is not limited to the scope of the present disclosure. Alternatives and modifications to the embodiments of the present disclosure by those of ordinary skill in the art are within the scope of the present disclosure.

What is claimed is:

1. An error amplifier for a switching converter, comprising:
an operation module, configured to output a regulation signal according to a difference between a feedback voltage and a reference voltage, wherein the feedback voltage represents an output voltage of the switching converter, and the regulation signal is used to regulate an output current of the switching converter;
a regulation module, configured to regulate a transconductance of the operation module according to an absolute value of the difference between the feedback voltage and the reference voltage upon the absolute value of the difference between the feedback voltage and the reference voltage is greater than or equal to a preset difference threshold; or regulate the transconductance of the operation module according to an absolute value of the regulation signal upon the absolute value of the regulation signal is greater than or equal to a preset threshold.

2. The error amplifier according to claim 1, wherein upon the absolute value of the difference between the feedback voltage and the reference voltage is less than the preset difference threshold, or the absolute value of the regulation signal is less than the preset threshold, the transconductance of the operation module remains unchanged.

3. The error amplifier according to claim 1, wherein the regulation module controls the transconductance to be positively correlated with the absolute value of the difference between the feedback voltage and the reference voltage, or controls the transconductance to be positively correlated with the absolute value of the regulation signal.

4. The error amplifier according to claim 1, wherein the operation module comprises a differential input unit, a current mirror unit and a tail current unit,
the tail current unit provides a preset tail current to the differential input unit, the differential input unit converts the feedback voltage to a first current, the reference voltage to a second current, and the current mirror unit outputs the regulation signal according to a difference between the first current and the second current.

5. The error amplifier according to claim 4, wherein the regulation module comprises a tail current regulation unit that regulates a total tail current of the operation module according to the absolute value of the difference between the feedback voltage and the reference voltage, or regulates the total tail current of the operation module according to the absolute value of the regulation signal.

6. The error amplifier according to claim 5, wherein the tail current regulation unit comprises a first pair of differential input transistors and a first current mirror assembly, an output terminal of the first current mirror assembly is connected to the differential input unit, the first pair of differential input transistors convert the feedback voltage to a first regulation current, convert the reference voltage to a second regulation current, and the first current mirror assembly outputs a third regulation current according to the absolute value of a difference between the first regulation current and the second regulation current.

7. The error amplifier according to claim 5, wherein the tail current regulation unit comprises a third current mirror assembly, a reference terminal of the third current mirror assembly is connected to an output terminal of the current mirror unit, an output terminal of the third current mirror assembly is connected to the differential input unit, and outputs a seventh regulation current according to an absolute value of the regulation signal.

8. The error amplifier according to claim 4, wherein the regulation module comprises a proportional factor regulation unit, the proportional factor regulation unit regulates a proportional factor of the current mirror unit according to the absolute value of the difference between the feedback voltage and the reference voltage, or regulates the proportional factor of the current mirror unit according to the absolute value of the regulation signal, wherein
the proportional factor represents a ratio of an output current of the current mirror unit to a reference current.

9. The error amplifier according to claim 8, wherein the proportional factor regulation unit comprises a second pair of differential input transistors, a second current mirror assembly and a resistor assembly, the resistor assembly is connected between an output terminal of the second current mirror assembly and a reference terminal of the current mirror unit, the second pair of differential input transistors convert the feedback voltage to a fourth regulation current and the reference voltage to a fifth regulation current, the second current mirror assembly outputs a sixth regulation current according to an absolute value of a difference between the fourth regulation current and the fifth regulation current, and the sixth regulation current flowing through the resistor assembly.

10. A switching converter, comprising the error amplifier according to claim 1.

11. A control method of an error amplifier for a switching converter, comprising:
regulating a transconductance of the error amplifier according to an absolute value of a difference between a feedback voltage and a reference voltage, or regulating the transconductance of the error amplifier according to an absolute value of a regulation signal, wherein
the feedback voltage represents an output voltage of the switching converter, the regulation signal is acquired according to a difference between the feedback voltage and the reference voltage and is used to regulate an output current of the switching converter.

12. The control method according to claim 11, wherein regulating a transconductance of the error amplifier according to an absolute value of a difference between a feedback voltage and a reference voltage, or regulating the transconductance of the error amplifier according to an absolute value of a regulation signal comprises:
in a first regulation state, controlling a transconductance of an operation module unchanged;
in a second regulation state, controlling the transconductance of the operation module to be positively correlated with the absolute value of the difference between the feedback voltage and the reference voltage, or controlling the transconductance of the operation module to be positively correlated with the absolute value of the regulation signal, wherein
in the first regulation state, the absolute value of the difference between the feedback voltage and the reference voltage is less than a preset difference threshold, or the absolute value of the regulation signal is less than a preset threshold;
in the second regulation state, the absolute value of the difference between the feedback voltage and the reference voltage is greater than or equal to the preset difference threshold, or the absolute value of the regulation signal is greater than or equal to the preset threshold.
